(19) United States
(12) Patent Application Publication
(10) Pub. No.: US 2024/0006399 A1
(43) Pub. Date: Jan. 4, 2024

(54) DIE-STACKED AND MOLDED ARCHITECTURE FOR MEMORY ON PACKAGE (MOP)

(71) Applicant: Intel Corporation, Santa Clara, CA (US)

(72) Inventors: Seok Ling Lim, Kulim (MY); Chan Kim Lee, BAYAN LEPAS 07 (MY); Eng Huat Goh, Penang (MY); Jenny Shio Yin Ong, Bayan Lepas (MY); Tin Poay Chuah, Bayan Lepas (MY)

(73) Assignee: Intel Corporation, Santa Clara, CA (US)

(21) Appl. No.: 17/853,329

(22) Filed: Jun. 29, 2022

(51) Int. Cl. H01L 25/18; H01L 25/065; H01L 23/31; H01L 23/367; H01L 25/00; H01L 21/56; H01L 21/48; H01L 23/552

(52) U.S. Cl. CPC H01L 25/18; H01L 25/0652; H01L 23/3185; H01L 23/367; H01L 25/50; H01L 21/56; H01L 21/486; H01L 23/552; H01L 23/5386

(57) ABSTRACT

An electronic device includes a package substrate; a memory integrated circuit (IC) mounted on the package substrate; a mold layer including one or more chiplets and a base IC die within the mold layer, the one or more chiplets arranged on the base IC die; a top chiplet mounted on a surface of the mold layer, wherein a combined height of the mold layer and the top chiplet substantially matches a height of the memory IC; and a heat spreader having a uniform surface contacting the memory IC and the top chiplet.

### TECHNICAL FIELD

Embodiments pertain to packaging of integrated circuits (ICs). Some embodiments relate to IC package interconnection of integrated circuits.

### BACKGROUND

Electronic systems often include integrated circuits (ICs) that are interconnected and packaged as a subassembly. It is desired to integrate multiple types of IC dies into a single package to create an efficient system in a package. However, as packaged electronic systems become larger due to adding more IC dies, the mismatch in form factor of the dies makes it challenging to integrate the dies into an electronic package efficiently. Thus, there are general needs for devices, systems and methods that address the size challenges for interconnection and packaging of IC systems and yet provide a robust design.

### BRIEF DESCRIPTION OF THE DRAWINGS

FIG. 1 is an illustration of an example of an electronic device in accordance with some embodiments;

FIGS. 2A-2B are a cross section view and a top view, respectively, of another example of an electronic device in accordance with some embodiments;

FIG. 3 is a cross section view of another example of an electronic device in accordance with some embodiments;

FIG. 4 is a cross section view of another example of an electronic device in accordance with some embodiments;

FIGS. 5A-5I illustrate a flow diagram of a method of manufacture of an electronic device in accordance with some embodiments;

FIG. 6 illustrates a system level diagram in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

To meet the demand for increased functional complexity in smaller devices, manufacturers integrate multiple types of IC dies in a single electronic package to create an efficient electronic system in a package. However, the desire to include multiple dies from different manufacturers into the same electronics package can be challenging. Mismatch in die form factor of electronic systems has led to the approach of a heat spreader with a pedestal design. A pedestal heat spreader has multiple heights or thicknesses. Memory silicon can be thicker than other silicon. To implement a system with Memory on Package (MoP) architecture, manufacturer's use a pedestal heat spreader that contacts ICs at different heights to ensure efficiency of thermal solution.

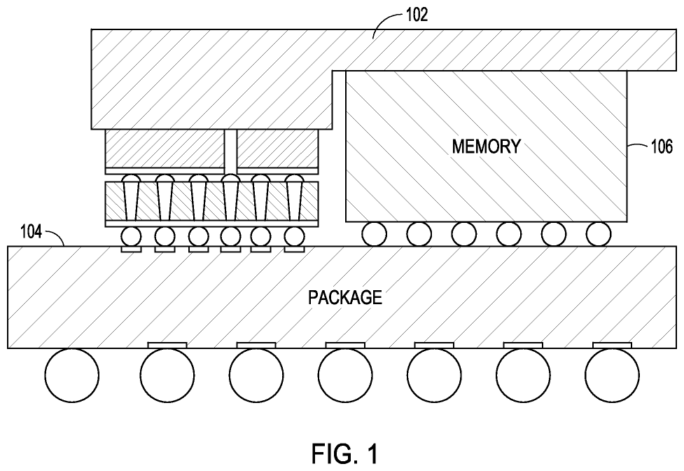

FIG. 1 is a cross section view of an example of an electronic device with an MoP architecture that uses a pedestal heat spreader 102. The heat spreader has two different heights to make up for the difference in height of the ICs in the system. Using a pedestal heat spreader 102 instead of a conventional heat spreader may be undesirable due to the cost of using an unconventional part. Additionally, there may be a signal integrity issue due to one or both of electromagnetic interference (EMI) or radio frequency interference (RFI) in routing signals in the package substrate 104 between the memory IC 106 and the other ICs of the package.

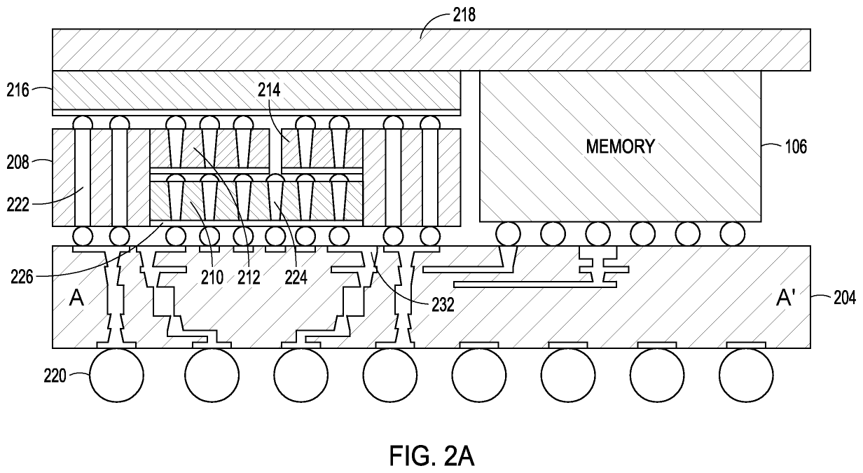

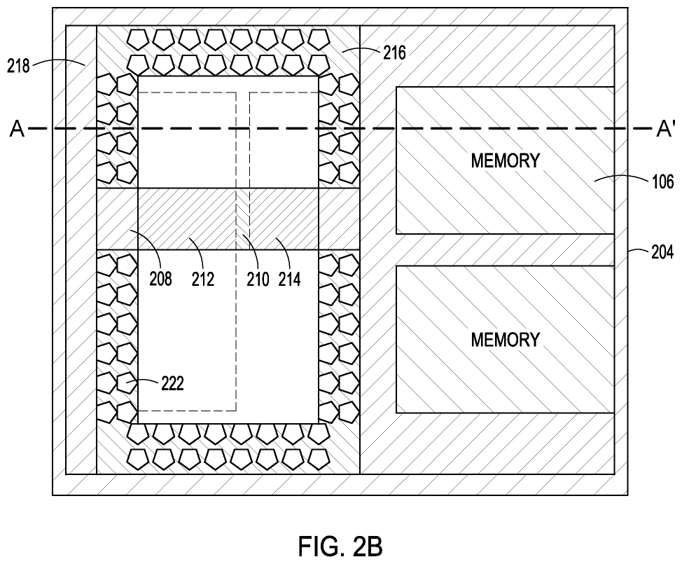

FIGS. 2A and 2B are a cross section view and a top view, respectively, of another example of an electronic device with an improved MoP architecture. The device includes a package substrate 204, and a memory IC 106 mounted on the package substrate 204, and a mold layer 208. The package substrate 204 can include a ball grid array (BGA) of solder bumps 220 attached to bonding pads for bonding to another substrate (e.g., a mother board). The mold layer 208 includes one or more chiplets and a base IC die 210 within the mold layer 208. In the example of FIG. 2, the mold layer 208 includes two chiplets 212, 214 (e.g., a compute chiplet and a System on Chip (SoC) chiplet) stacked on the base IC die 210. The device also includes a top chiplet 216 arranged on the top surface of the mold layer 208. The height of the mold layer 208 and the top chiplet 216 substantially matches the height of the memory IC 106. The device is topped by a heat spreader 218 contacting the memory IC 106 and the top chiplet 216. The heat spreader 218 is not a pedestal design and has a uniform thickness and a uniform bottom surface that contacts the memory IC 106 and the top chiplet 216. Thus, the disadvantages of using a pedestal design heat spreader are removed.

The mold layer 208 includes through mold vias (TMVs) 222. At least one of the TMVs 222 provides electrical continuity between the interconnect of package substrate 204 and the top chiplet 216. FIG. 2B shows that TMVs can be arranged around the periphery of the chiplets 212, 214 and the base IC die 210. If the TMVs 222 are connected to a circuit ground plane (e.g., Vss) or other shield voltage, the TMVs can form a shield wall around the chiplets 212, 214 to reduce EMI/RFI.

Returning to FIG. 2A, the base IC die 210 may be a passive component. The base IC die 210 can include through silicon vias (TSVs) 224 to provide electrical continuity between the interconnect of package substrate 204 and the chiplets 212, 214. The base IC die 210 may be an active component that includes an active layer 226. In certain example, the base IC die 210 is also a chiplet. The chiplets 212, 214 may also include TSVs 224 to provide electrical continuity between the base IC die 210 and the top chiplet 216. The TSVs 224 of the base IC die and the chiplets 212, 214 may provide electrical continuity between the interconnect of the package substrate 204 and the top chiplet 216. In certain examples, the TSVs 224 connect power or circuit ground from the package substrate 204 to the top chiplet 216.

The top chiplet 216 can be either a passive or an active component. In some examples, the top chiplet 216 includes at least one metal-insulator-metal (MIM) capacitor, and the mold layer 208 includes at least one TMV 222 that provides electrical continuity from the package substrate to an MIM capacitor of the top chiplet 216.

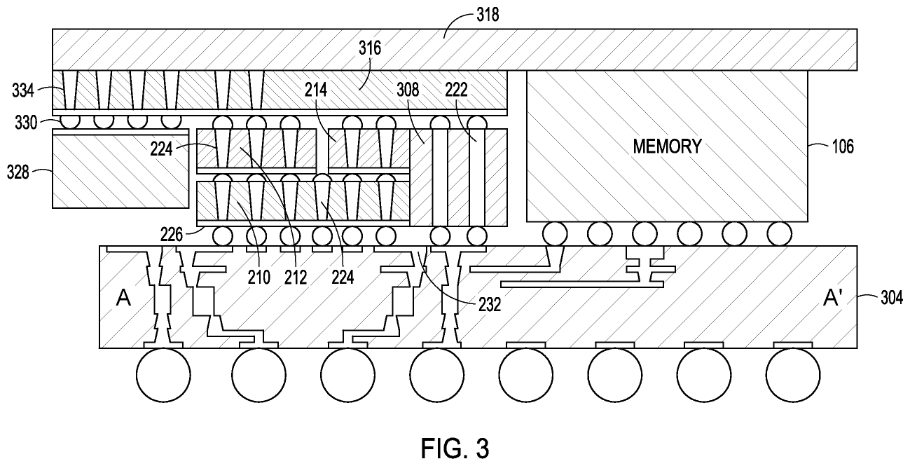

FIG. 3 is a cross section view of another example of an electronic device. The device includes a package substrate 304, and a memory IC 106 mounted on the package substrate 304, and a mold layer 308. The mold layer 308 includes a base IC die 210 and chiplets 212, 214. A top chiplet 316 is arranged on the top surface of the mold layer 308. The height of the mold layer 308 and the top chiplet 316 substantially matches the height of the memory IC 106, and the device is topped by a heat spreader 318 contacting the memory IC 106 and the top chiplet 316. The heat spreader 318 does not have a pedestal design and has a uniform thickness and a uniform bottom surface that contacts the memory IC 106 and the top chiplet 316.

The device includes another chiplet (e.g., a fourth chiplet 328) outside the mold layer and bonded to the top chiplet 316. The fourth chiplet 328 may be attached to the top chip 316 using solder bumps (e.g., microbumps 330). The fourth chiplet 328 may be a cache chiplet, an input-output extender (IOE) chiplet (e.g., for a Peripheral Component Interconnect Express (PCIe) interface, a Universal Serial Bus C (USB-C) interface, etc.), a platform controller hub (PCH) chiplet, a digital signal processor (DSP) chiplet, etc. The mold layer 308 includes TMVs 222 arranged between the chiplet stack and the memory IC 106. The TMVs 222 may be connected to a shield voltage to provide a shield wall on one side or up to three sides of the chiplet stack. The top chiplet 316 can include one or more TSVs 334 to provide interconnect between the chiplets 328, 212, and 214.

The substrates of the devices in FIGS. 3 and 2A include an electrically conductive microstrip 232 to carry a memory signal between the memory IC 106 and the one or more chiplets 212, 214. As explained previously herein, there may be a signal integrity issue due to EMI/RFI in routing signals in the microstrip 232 between the memory IC 106 and the other ICs of the electronic device.

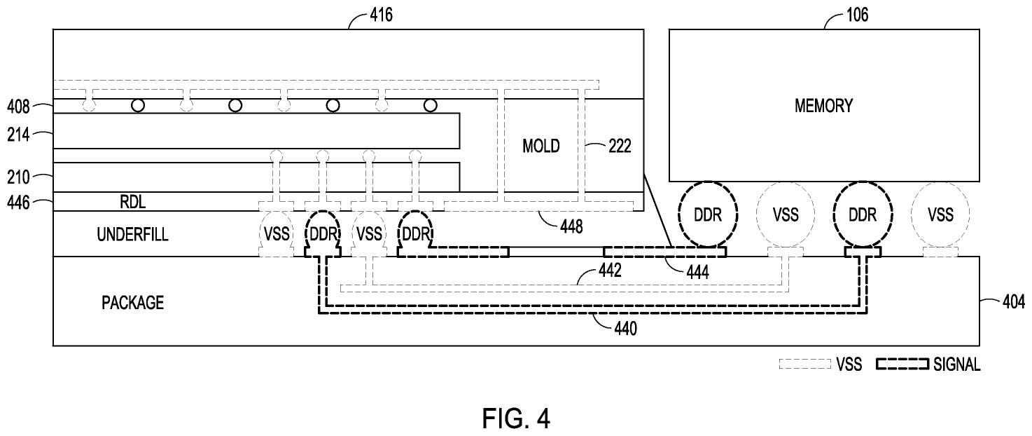

FIG. 4 is a cross section view of portions of another example of an electronic device. The device includes a package substrate 404, and a memory IC 106 mounted on the package substrate 404, and a mold layer 408. The mold layer 408 includes a base IC die 210 and one or more chiplets 214. A top chiplet 416 is arranged on the top surface of the mold layer 408. The height of the mold layer 408 and the top chiplet 416 substantially matches the height of the memory IC 106. A heat spreader (not shown) having a uniform bottom surface may be arranged on the memory IC 106 and the top chiplet 416.

The package substrate 404 includes one or more electrically conductive microstrips 440 that carry a memory signal (e.g., a double data rate or DDR memory signal) between the memory IC 106 and a die (e.g., base die 210 or chiplet 214) that is within the mold layer 408. The package substrate 404 also includes a shield layer 442 or shield trace to shield the microstrip 440 from EMI/RFI. The shield layer or shield trace is connected to a shield voltage (e.g., circuit ground or Vss).

The package substrate 404 may include one or more electrically conductive surface microstrips 444 on a surface of the package substrate 404 to carry a signal between the memory IC and the one or more chiplets within the mold layer. The electronic device includes a redistribution layer (RDL) 446 disposed between the mold layer 408 and the package substrate 404. The RDL 446 includes a shield layer 448 or shield trace to shield the surface microstrip 444 from EMI/RFI. The shield layer 448 or shield trace can be connected to the shield voltage by the TMVs 222.

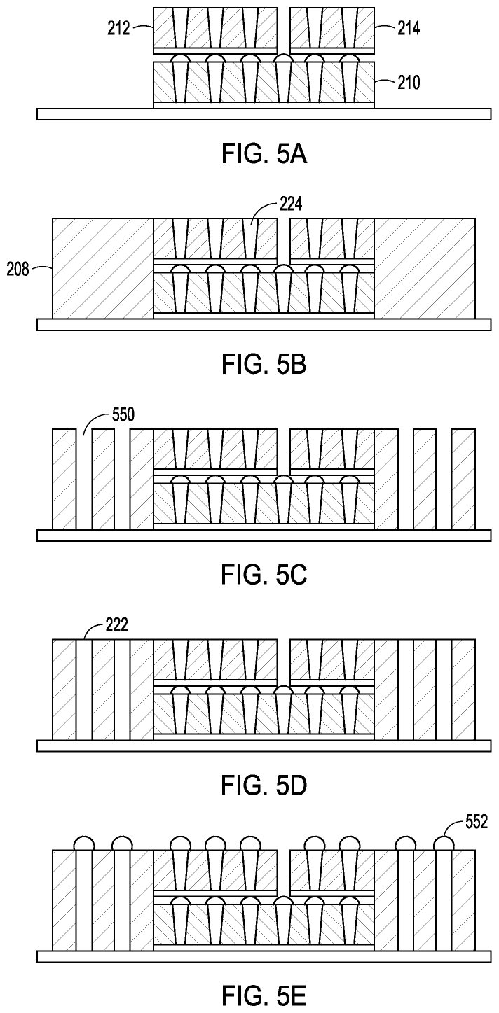

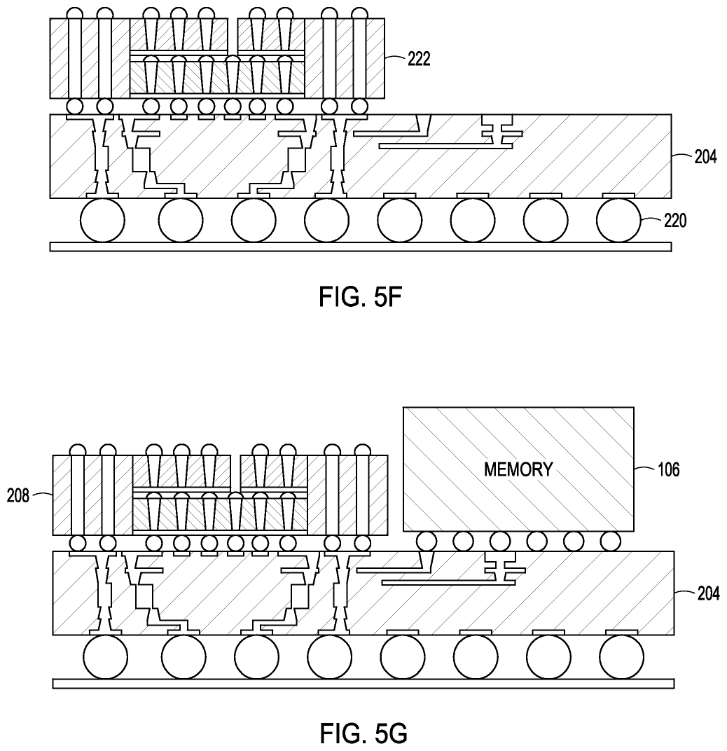

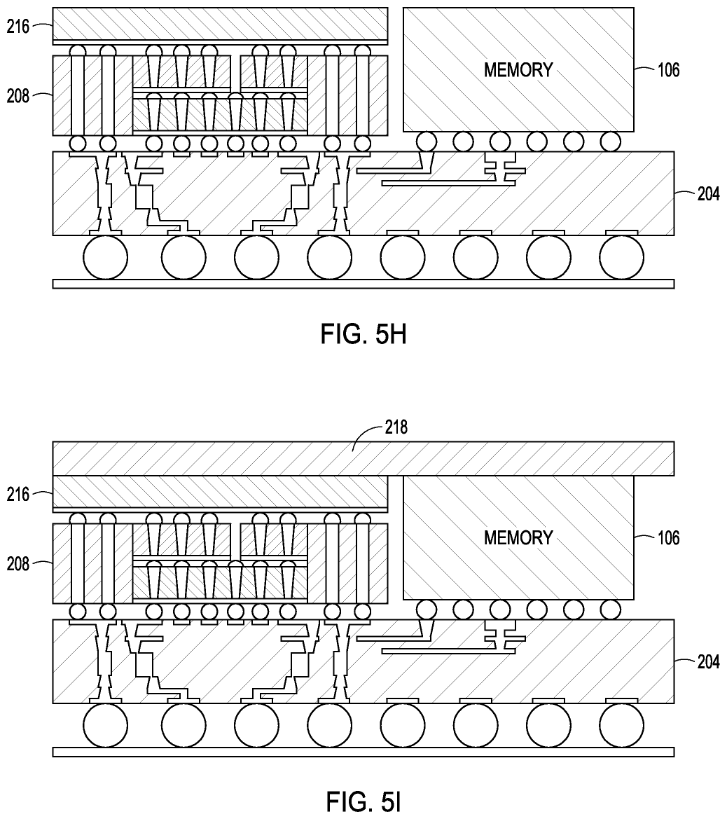

FIGS. 5A-5I illustrate a flow diagram of a method of manufacture of an electronic device, such as the electronic device of FIGS. 2A, 2B. In FIG. 5A, multiple IC dies are stacked and placed on a tray. One or more of the IC dies may be chiplets and the stacked dies may be a chiplet stack. The example of FIG. 5A shows two chiplets 212, 214 stacked on a base IC die 210, but the IC dies may be stacked in other arrangements and include a different number of IC dies.

In FIG. 5B, a mold layer 208 is formed around the chiplet stack. The top surface of the mold layer 208 may be ground down to the surface of the top IC dies. The IC dies can include TSVs 224 and the grinding can expose the top of the TSVs 224.

In FIG. 5C, voids 550 are patterned in the mold layer 208 (e.g., by drilling). The voids are for TMVs and the voids 550 may be arranged around the chiplet stack to form a shield wall around the chiplet stack. In FIG. 5D, the voids 550 are filled (e.g., by plating or printing) with an electrically conductive material (e.g., a metal such as copper) for the TMVs 222. In FIG. 5E, solder bumps (e.g., microbumps 552) are formed on the ends of the TMVs 222 (e.g., with a stencil).

In FIG. 5F, the mold layer 208 and chiplet stack are placed on a package substrate 204. Solder bumps 220 may be added in a BGA on the bottom surface of the package substrate 204. In FIG. 5G, a memory IC 106 is placed on the package substrate 204. The package substrate 204 includes interconnect between the IC die of the chiplet stack and the memory IC 106.

In FIG. 5H, a top chiplet 216 is placed on the top surface of the chiplet stack and mold layer 208. The top chiplet may include an MIM structure and include an MIM capacitor. The top chiplet 216 may include interconnect that is connected (e.g., by solder bumps) to one or more TMVs 222 of the mold layer 208. In FIG. 5I, a heat spreader 218 is placed on the top chiplet 216 and memory IC 106. The height of the top chiplet 216, the chiplet stack, and mold layer 208 is substantially equal to the height of the memory IC 106, so that a heat spreader with a uniform surface can be used instead of a pedestal heat spreader having two different thicknesses to match different heights of components.

An example of an electronic device using assemblies with the system level packaging as described in the present disclosure is included to show an example of a higher level device application.

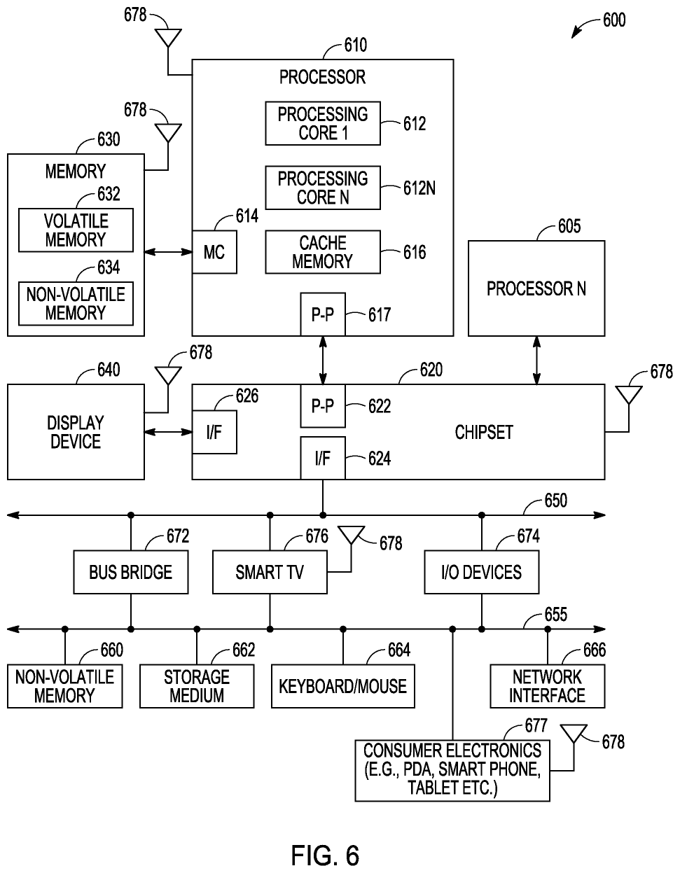

FIG. 6 illustrates a system level diagram, according to one embodiment of the invention. For instance, FIG. 6 depicts an example of an electronic device (e.g., system) that can include one or more of interposers (e.g., glass interposers) as described in the present disclosure. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 is a system on a chip (SOC) system. In one example, two or more systems as shown in FIG. 6 may be coupled together using one or more glass interposers as described in the present disclosure.

In one embodiment, processor 610 has one or more processing cores 612 and 612N, where N is a positive integer and 612N represents the Nth processor core inside processor 610. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, the wireless antenna interface 678 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the invention, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices 672, 676, 674, 660, 662, 664, 666, 677, etc. Buses 650 and 655 may be interconnected together via a bus bridge 672. Chipset 620 connects to one or more buses 650 and 655 that interconnect various elements 674, 660, 662, 664, and 666. Chipset 620 may also be coupled to a wireless antenna 678 to communicate with any device configured to transmit and/or receive wireless signals. Chipset 620 connects to display device 640 via interface (I/F) 626. Display 640 may be, for example, a liquid crystal display (LCD), a plasma display, cathode ray tube (CRT) display, or any other form of visual display device. In some embodiments of the invention, processor 610 and chipset 620 are merged into a single SOC. In one embodiment, chipset 620 couples with (e.g., via interface 624) a non-volatile memory 660, a mass storage medium 662, a keyboard/mouse 664, and a network interface 666 via I/F 624 and/or I/F 626, I/O devices 674, smart TV 676, consumer electronics 677 (e.g., PDA, Smart Phone, Tablet, etc.).

In one embodiment, mass storage medium 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

The devices, systems, and methods described can provide improved routing of interconnection between ICs for a multichip package in addition to providing improved transistor density in the IC die. Examples described herein include two or three IC dies for simplicity, but one skilled in the art would recognize upon reading this description that the examples can include more than three IC dice.

To better illustrate the method and apparatuses disclosed herein, a non-limiting list of embodiments is provided here:

Example 1 includes subject matter (such as an electronic device) comprising a package substrate; a memory integrated circuit (IC) mounted on the package substrate; a mold layer including one or more chiplets and a base IC die within the mold layer, the one or more chiplets arranged on the base IC die; a top chiplet mounted on a surface of the mold layer, wherein a combined height of the mold layer and the top chiplet substantially matches a height of the memory IC; and a heat spreader having a uniform surface contacting the memory IC and the top chiplet.

In Example 2, the subject matter of Example 1 optionally includes a mold layer includes at least one through mold via (TMV) that provides electrical continuity from the package substrate to the top chiplet.

In Example 3, the subject matter of Example 2 optionally includes a mold layer including multiple TMVs that are electrically connected to a circuit ground plane and are arranged around the periphery of the one or more chiplets.

In Example 4, the subject matter of one or any combination of Examples 1-3 optionally includes a redistribution layer (RDL) disposed between the mold layer and the package substrate; and a package substrate including an electrically conductive surface microstrip on a surface of the package substrate to carry a signal between the memory IC and the one or more chiplets within the mold layer, and an RDL including a shield layer to shield the surface microstrip from electromagnetic interference (EMI).

In Example 5, the subject matter of one or any combination of Examples 1-4 optionally includes a package substrate including an electrically conductive microstrip to carry a memory signal between the memory IC and the one or more chiplets within the mold layer, and a shield layer to shield the microstrip from EMI.

In Example 6, the subject matter of Example 5 optionally includes a base IC die includes a first through silicon via (TSV) connected to the microstrip and the one or more chiplets, and at least a second TSV connected to the shield layer of the RDL and the one or more chiplets.

In Example 7, the subject matter of one or any combination of Examples 1-6 optionally includes a top chiplet that includes at least one metal-insulator-metal (MIM) capacitor, and the mold layer includes at least one through mold via (TMV) that provides electrical continuity from the package substrate to an MIM capacitor of the top chiplet.

In Example 8, the subject matter of one or any combination of Examples 1-7 optionally includes one or more chiplets within the mold layer that includes a system on chip (SoC) chiplet and a compute chiplet stacked on the base IC die, and a top chiplet including at least one MIM capacitor.

In Example 9, the subject matter of Example 8 optionally includes a fourth chiplet outside the mold layer and bonded to the top chiplet, and the the mold layer including multiple TMVs that are electrically connected to a circuit ground plane and are arranged between the one or more chiplets within the mold layer and the memory IC.

Example 10 includes subject matter (such as a method of forming an electronic device) or can optionally be combined with one or any combination of Examples 1-9 to include such subject matter, comprising forming a chiplet stack that includes multiple chiplets and a base IC die, forming a mold layer around the chiplet stack, placing the chiplet stack on a package substrate, placing a memory integrated circuit (IC) on the package substrate, placing a top chiplet on a surface of the chiplet stack, a height of the top chiplet and chiplet stack being substantially equal to a height of the memory IC, and placing a heat spreader having a uniform surface on the memory IC and top chiplet.

In Example 11, the subject matter of Example 10 optionally includes forming voids in the mold layer around the chiplet stack; and filling the voids with an electrically conductive material to form through mold vias (TMVs) around the chiplet stack.

In Example 12, the subject matter of one or both of Examples 10 and 11 optionally includes forming voids in the mold layer between the chiplet stack and the memory IC, filling the voids with an electrically conductive material to form through mold vias (TMVs) between the chiplet stack and the memory IC, placing an input-output extender (IOE) chiplet on a side of the chiplet stack not adjacent to the memory IC, and attaching the IOE chiplet to the top chiplet, wherein the top chiplet includes at least one interconnection between the IOE chiplet and a chiplet of the chiplet stack.

In Example 13, the subject matter of one or any combination of Examples 10-12 optionally includes forming at least one electrically conductive surface microstrip on a surface of the package substrate; and arranging a redistribution layer (RDL) between the chiplet stack and the package substrate, wherein the RDL includes a shield layer to shield the surface microstrip from electromagnetic interference (EMI).

In Example 14, the subject matter of one or any combination of Examples 10-13 optionally includes forming at least one electrically conductive microstrip in the package substrate, forming a shield layer for the microstrip, and connecting the shielded microstrip to an input-output (I/O) pad of the memory IC and to an I/O pad of a chiplet of the multiple chiplets.

In Example 15, the subject matter of one or any combination of Examples 10-14 optionally includes grinding a surface of the mold layer to expose I/O connections of at least one chiplet of the multiple chiplets, and attaching solder bumps to the I/O connections of the at least one chiplet and the TMVs.

Example 16 includes subject matter (such as a package electronic system) or can optionally be combined with one or any combination of Examples 1-15 to include such subject matter, comprising a package substrate; a memory integrated circuit (IC) mounted on the package substrate; a mold layer including multiple chiplets within the mold layer, the multiple chiplets including at least one chiplet stacked on a base IC die; a redistribution layer (RDL) disposed between the mold layer and the package substrate; and the package substrate includes an electrically conductive surface microstrip on a surface of the package substrate to carry a signal between the memory IC and the at least one chiplet of the multiple chiplets within the mold layer, and the RDL includes a shield layer to shield the surface microstrip from electromagnetic interference (EMI).

In Example 17, the subject matter of Example 16 optionally includes a package substrate including an electrically conductive microstrip to carry a memory signal between the memory IC and the at least one chiplet of the multiple chiplets within the mold layer; and a mold layer including at least one through mold via (TMV) that provides electrical continuity from the package substrate to the MIM capacitor of the top chiplet.

In Example 18, the subject matter of one or both of Examples 16 and 17 optionally includes an electrically conductive microstrip to carry a memory signal between the memory IC and the at least one chiplet of the multiple chiplets within the mold layer, and a shield layer to shield the microstrip from EMI.

In Example 19, the subject matter of Example 18 optionally includes a mold layer including multiple TMVs that are electrically connected to a circuit ground plane and are arranged around the periphery of the multiple chiplets.

In Example 20, the subject matter of one or any combination of Examples 16-19 optionally includes a base IC die including a first through silicon via (TSV) connected to the microstrip and the at least one chiplet of the multiple chiplets, and at least a second TSV connected to the shield layer of the RDL and the at least one chiplet.

In Example 21, the subject matter of one or any combination of Examples 16-20 optionally includes multiple chiplets within the mold layer including a first chiplet and a second chiplet stacked on the base IC die, and an input-output (I/O) pad of the first chiplet is connected to an I/O pad of the second chiplet by the through silicon interconnect of the top chiplet.

These non-limiting example embodiments can be combined in any permutation or combination. Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. An electronic device comprising:
a package substrate;
a memory integrated circuit (IC) mounted on the package substrate;
a mold layer including one or more chiplets and a base IC die within the mold layer, the one or more chiplets arranged on the base IC die;
a top chiplet mounted on a surface of the mold layer, wherein a combined height of the mold layer and the top chiplet substantially matches a height of the memory IC; and
a heat spreader having a uniform surface contacting the memory IC and the top chiplet.

2. The electronic device of claim 1, wherein the mold layer includes at least one through mold via (TMV) that provides electrical continuity from the package substrate to the top chiplet.

3. The electronic device of claim 2, wherein the mold layer includes multiple TMVs that are electrically connected to a circuit ground plane and are arranged around the periphery of the one or more chiplets.

4. The electronic device of claim 1, including:
a redistribution layer (RDL) disposed between the mold layer and the package substrate; and
wherein the package substrate includes an electrically conductive surface microstrip on a surface of the package substrate to carry a signal between the memory IC and the one or more chiplets within the mold layer, and the RDL includes a shield layer to shield the surface microstrip from electromagnetic interference (EMI).

5. The electronic device of claim 1, wherein the package substrate includes:
an electrically conductive microstrip to carry a memory signal between the memory IC and the one or more chiplets within the mold layer; and
a shield layer to shield the microstrip from EMI.

6. The electronic device of claim 5, wherein the base IC die includes a first through silicon via (TSV) connected to the microstrip and the one or more chiplets, and at least a second TSV connected to the shield layer of the RDL and the one or more chiplets.

7. The electronic device of claim 1, wherein the top chiplet includes at least one metal-insulator-metal (MIM) capacitor, and the mold layer includes at least one through mold via (TMV) that provides electrical continuity from the package substrate to an MIM capacitor of the top chiplet.

8. The electronic device of claim 1,
wherein the one or more chiplets within the mold layer include a system on chip (SoC) chiplet and a compute chiplet stacked on the base IC die; and
wherein the top chiplet includes at least one MIM capacitor.

9. The electronic device of claim 8, including:
a fourth chiplet outside the mold layer and bonded to the top chiplet; and
wherein the mold layer includes multiple TMVs that are electrically connected to a circuit ground plane and are arranged between the one or more chiplets within the mold layer and the memory IC.

10. A method of forming an electronic device, the method comprising:
forming a chiplet stack that includes multiple chiplets and a base IC die;
forming a mold layer around the chiplet stack;
placing the chiplet stack on a package substrate;
placing a memory integrated circuit (IC) on the package substrate;
placing a top chiplet on a surface of the chiplet stack, a height of the top chiplet and chiplet stack being substantially equal to a height of the memory IC; and
placing a heat spreader having a uniform surface on the memory IC and top chiplet.

11. The method of claim 10, including:
forming voids in the mold layer around the chiplet stack; and
filling the voids with an electrically conductive material to form through mold vias (TMVs) around the chiplet stack.

12. The method of claim 10, including:
forming voids in the mold layer between the chiplet stack and the memory IC;
filling the voids with an electrically conductive material to form through mold vias (TMVs) between the chiplet stack and the memory IC;
placing an input-output extender (IOE) chiplet on a side of the chiplet stack not adjacent to the memory IC; and
attaching the IOE chiplet to the top chiplet, wherein the top chiplet includes at least one interconnection between the IOE chiplet and a chiplet of the chiplet stack.

13. The method of claim 10, including:
forming at least one electrically conductive surface microstrip on a surface of the package substrate; and
arranging a redistribution layer (RDL) between the chiplet stack and the package substrate, wherein the RDL includes a shield layer to shield the surface microstrip from electromagnetic interference (EMI).

14. The method of claim 10, including:
forming at least one electrically conductive microstrip in the package substrate;
forming a shield layer for the microstrip; and
connecting the shielded microstrip to an input-output (I/O) pad of the memory IC and to an I/O pad of a chiplet of the multiple chiplets.

15. The method of claim 10, including:
grinding a surface of the mold layer to expose I/O connections of at least one chiplet of the multiple chiplets; and
attaching solder bumps to the I/O connections of the at least one chiplet and the TMVs.

16. A packaged electronic system, the system comprising:
a package substrate;
a memory integrated circuit (IC) mounted on the package substrate;
a mold layer including multiple chiplets within the mold layer, the multiple chiplets including at least one chiplet stacked on a base IC die;
a redistribution layer (RDL) disposed between the mold layer and the package substrate; and
wherein the package substrate includes an electrically conductive surface microstrip on a surface of the package substrate to carry a signal between the memory IC and the at least one chiplet of the multiple chiplets within the mold layer, and the RDL includes a shield layer to shield the surface microstrip from electromagnetic interference (EMI).

17. The system of claim 16, wherein the package substrate includes:
an electrically conductive microstrip to carry a memory signal between the memory IC and the at least one chiplet of the multiple chiplets within the mold layer; and
a shield layer to shield the microstrip from EMI.

18. The system of claim 16, including:
a top chiplet disposed on a surface of the mold layer that includes a metal-insulator-metal (MIM) capacitor; and
wherein the mold layer includes at least one through mold via (TMV) that provides electrical continuity from the package substrate to the MIM capacitor of the top chiplet.

19. The system of claim 18, wherein the mold layer includes multiple TMVs that are electrically connected to a circuit ground plane and are arranged around the periphery of the multiple chiplets.

20. The system of claim 16, wherein the base IC die includes a first through silicon via (TSV) connected to the microstrip and the at least one chiplet of the multiple chiplets, and at least a second TSV connected to the shield layer of the RDL and the at least one chiplet.

21. The system of claim 16, wherein the multiple chiplets within the mold layer include a first chiplet and a second chiplet stacked on the base IC die, and an input-output (I/O) pad of the first chiplet is connected to an I/O pad of the second chiplet by the through silicon interconnect of the top chiplet.
